(19) United States
(12) Patent Application Publication
(10) Pub. No.: US 2025/0309583 A1
(43) Pub. Date: Oct. 2, 2025

(54) CABLE HOLDING ASSEMBLY FOR AN ELECTRONIC DEVICE

(71) Applicant: Lenovo (Singapore) Pte. Ltd., Singapore (SG)

(72) Inventor: Cyan Godfrey, Chapel Hill, NC (US)

(21) Appl. No.: 18/619,544

(22) Filed: Mar. 28, 2024

(51) Int. Cl. H01R 13/58; H05K 5/02

(52) U.S. Cl. CPC H01R 13/582; H01R 13/5837; H05K 5/0247

(57) ABSTRACT

A cable holding assembly for an electronic device is provided that can include a cable holding device having a cable holding body with a first pliable member having a first pliable wing and a second pliable member having a second pliable wing that are both configured to deflect away from a center axis of a gap holding a first cable in response to a first linear force applied by the first cable. The first pliable wing of the first pliable member and second pliable wing of the second pliable member can also both be configured to deflect towards the center axis in response to a second linear force applied by the first cable disposed within the first gap to apply a compression force on the first cable when the first linear force is in an opposite direct to the second linear force.

### FIELD

The present disclosure relates generally to a cable holding assembly for an electronic device.

### BACKGROUND OF THE INVENTION

As electronic devices continue to advance, the number of input ports for such electronic devices continues to increase. Such input ports can include power cords, USB ports including USB-A, USB-B, USB-C, etc., HDMI ports, serial ports, ethernet ports, or the like. In addition, oftentimes more than one type of port may be provided as well, such as multiple USB ports. When all of these input ports are utilized, certain electronic devices can have as many as ten or more input cables inserted into the electronic device, typically all on one side of the electronic device. Alternatively, while a couple of ports can be located on different sides of the electronic device, usually one side, such as the back side, include a majority of the ports.

As a result of the use of so many input ports and accompanying power cables, communication cables, etc., the number of cables can be both unsightly and very difficult to manage. As electronic devices continue to become smaller, the amount of space for securing these cables becomes more and more limited. This limited space can cause cables to become tangled, and intrusive. For example, when an electronic device already has numerous cables plugged into input ports and a new cable needs to be plugged into an input port disposed between input ports that already have cables, such installation can become cumbersome and lead to frustrations. In addition, each cable needs to be held securely in place so that the cables do not become dislodged, or the contact area between the input end of the cable and cable port compromised. These instances can result in the loss of power or connection between the electronic device and cable.

Addressing this problem is not easily accomplished. For starters, not all cables are the same. Cables can have different shapes, different diameters and different input ends (e.g., plugs). Consequently, a one size fits all solution is not suitable.

One way to attempt to solve problems associated with having so many cables in such a small area that all need to be securely held in place is to provide a single clamp that holds all of the cables together. While this is less time consuming than attempting to untangle and straighten out cables manually, drawbacks remain. For example, when a new cable is desired to be inserted into an unused input port the clamp is released and the same problem with getting the cable input end into the input port that is between cables remains. Additionally, often such clamps require the use of a tool or act as a door that locks down onto the cables to pinch them in place. Such additional force can wear down the cables and continue to lead to frustration. Thus a need exists for a solution to securing numerous cables into input ports of an electronic device.

### SUMMARY

In accordance with embodiments herein, a cable holding assembly for an electronic device is provided that can include a cable holding device having a cable holding body with a first arcuate slot configured to receive a first cable and a second arcuate slot configured to receive a second cable. The cable holding device can also include a first pliable member disposed between the first arcuate slot and the second arcuate slot, the first pliable member having a first pliable wing. The cable holding device may also include a second pliable member having a second pliable wing wherein a first gap having a center axis is formed between the first pliable wing of the first pliable member and the second pliable wing of the second pliable member. The first pliable wing of the first pliable member and second pliable wing of the second pliable member can both be configured to deflect away from the center axis in response to a first linear force applied by the first cable disposed within the first gap. The first pliable wing of the first pliable member and second pliable wing of the second pliable member can also both be configured to deflect towards the center axis in response to a second linear force applied by the first cable disposed within the first gap to apply a compression force on the first cable when the first linear force is in an opposite direct to the second linear force.

Optionally, the first pliable wing and second pliable wing may each be configured to compress the cable between one another when the second linear force is applied. In one aspect, the first pliable wing can be a first arcuate wing and the second pliable wing may be a second arcuate wing. In another aspect, the first pliable member can include a flat surface that extends between the first pliable wing and the second pliable wing. In yet another aspect, the width of the flat surface is based at least in part on the width of an input end of the cable. In one example, a width of the first gap can be based at least in part on a diameter of the cable. Optionally, the first gap may be configured to snuggly receive the cable.

In one aspect, the cable holding assembly can also include a body configured to couple to an electronic device and having a bottom tray configured to receive at least one input end of the cable. In one example the bottom tray can extend into a cable surface that includes the cable holding device. In another example the cable holding assembly can also include a cover coupled to the body and configured to allow access to the cable.

In accordance with embodiments herein, a cable holding assembly for an electronic device is provided that can include a body configured to couple to an electronic device and having a bottom tray configured to receive a first input end of a first cable and a second input end of a second cable while the first input end and second input end are inserted into a corresponding input port of the electronic device. The cable holding assembly can also include a cable holding device secured to the body and having a cable holding body with a first arcuate slot configured to receive the first cable and aligned with a first corresponding input port and a second arcuate slot configured to receive the second cable and aligned with a second corresponding input port. The cable holding device may also include a first pliable member disposed between the first arcuate slot and the second arcuate slot. The first pliable member can have a first pliable wing while a second pliable member has a second pliable wing wherein a first gap having a first center axis is formed between the first pliable wing of the first pliable member and the second pliable wing of the second pliable member. The first center axis may align with the first corresponding input port. The first pliable wing of the first pliable member and second pliable wing of the second pliable member are both configured to deflect away from the first center axis in response to a first linear force applied by the first cable. In addition, the first pliable wing of the first pliable member and second pliable wing of the second pliable member are both configured to deflect towards the first center axis in response to a second linear force applied by the first cable where the first linear force is in an opposite direct to the second linear force.

Optionally, the first pliable member can have a second pliable wing and the cable holding device can also include a third pliable member having a first pliable wing; wherein a second gap is formed between the second pliable wing of the first pliable member and the first pliable wing of the third pliable member. The second pliable wing of the first pliable member and the first pliable wing of the third pliable member may be both configured to deflect away from the second center axis in response to a first linear force applied by the second cable and deflect towards the second center axis in response to a second linear force applied by the second cable. The first linear force applied by the second cable is in an opposite direction to the second linear force applied by the second cable. In one aspect, the second gap can be configured to receive the second cable and align with the second corresponding input port. In another aspect, the first center axis may be parallel to the second center axis. In one example the first pliable wing can be a first arcuate wing and the second pliable wing can be a second arcuate wing. In one example, the first pliable member may be detachable from the cable holding assembly. In another example the cable holding assembly can also include a third arcuate slot where a first distance between the first arcuate slot and the second arcuate slot is a different distance than a second distance between the second arcuate slot and the third arcuate slot. In yet another example the cable holding device and the body can be of one-piece construction.

In accordance with embodiments herein a cable holding assembly for an electronic device is provided. The cable holding assembly can include a body configured to couple to an electronic device and having a bottom tray configured to receive at least one input end of a cable while the at least one input end is inserted into an input port of the electronic device. The bottom tray may extend into a cable surface having a similar height to the input port of the electronic device. The cable holding assembly can also include a cable holding device secured to the cable surface that includes a cable holding body with a first arcuate slot configured to receive a first cable and a second arcuate slot configured to receive a second cable. The cable holding device can also have a first pliable member disposed between the first arcuate slot and the second arcuate slot, the first pliable member having a first pliable wing. The cable holding device can also include a second pliable member having a second pliable wing where a first gap having a center axis is formed between the first pliable wing of the first pliable member and the second pliable wing of the second pliable member. The first pliable wing of the first pliable member and second pliable wing of the second pliable member can be both configured to deflect away from the center axis in response to a first linear force applied by a cable disposed within the first gap. The first pliable wing of the first pliable member and second pliable wing of the second pliable member can both be configured to deflect towards the center axis in response to a second linear force applied by the cable disposed within the first gap where the first linear force is in an opposite direct to the second linear force.

Optionally, the first pliable member can have a second pliable wing and the cable holding device may also include a third pliable member having a first pliable wing. A second gap can be formed between the second pliable wing of the first pliable member and the first pliable wing of the third pliable member. The second pliable wing of the first pliable member and the first pliable wing of the third pliable member can both be configured to deflect away from the second center axis in response to a first linear force applied by the second cable and deflect towards the second center axis in response to a second linear force applied by the second cable, where the first linear force applied by the second cable is in an opposite direction to the second linear force applied by the second cable.

### BRIEF DESCRIPTION OF THE DRAWINGS

FIG. 1 illustrates a front plan view of an electronic device in accordance with an embodiment.

FIG. 2 illustrates a top plan view of an electronic device with a cable holding assembly in accordance with an embodiment.

FIG. 3 illustrates a top plan view of an electronic device with a cable holding assembly holding cables in accordance with an embodiment.

FIG. 4 illustrates a back perspective view of an electronic device with a cable holding assembly in accordance with an embodiment.

FIG. 5 illustrates a back perspective view of an electronic device with a cable holding assembly in accordance with an embodiment.

FIG. 6 illustrates a perspective view of a cable holding device in accordance with an embodiment.

FIG. 7 illustrates a perspective view of a cable holding device holding cables in accordance with an embodiment.

FIG. 8 illustrates a partial plan view of a cable holding device in accordance with an embodiment.

FIG. 9 illustrates a partial plan view of a cable holding device with a cable in accordance with an embodiment.

### DETAILED DESCRIPTION

It will be readily understood that the components of the embodiments as generally described and illustrated in the figures herein, may be arranged and designed in a wide variety of different configurations in addition to the described example embodiments. Thus, the following more detailed description of the example embodiments, as represented in the figures, is not intended to limit the scope of the embodiments, as claimed, but is merely representative of example embodiments.

Reference throughout this specification to “one embodiment” or “an embodiment” (or the like) means that a particular feature, structure, or characteristic described in connection with the embodiment is included in at least one embodiment. Thus, appearances of the phrases “in one embodiment” or “in an embodiment” or the like in various places throughout this specification are not necessarily all referring to the same embodiment.

Furthermore, the described features, structures, or characteristics may be combined in any suitable manner in one or more embodiments. In the following description, numerous specific details are provided to give a thorough understanding of embodiments. One skilled in the relevant art will recognize, however, that the various embodiments can be practiced without one or more of the specific details, or with other methods, components, materials, etc. In other instances, well-known structures, materials, or operations are not shown or described in detail to avoid obfuscation. The following description is intended only by way of example, and simply illustrates certain example embodiments.

The term “pliable member” shall mean any object, element, piece of material, or the like that bends with a little amount of force applied, but remains stiff enough to exert a force to go back to its original form. The pliable member can be formed from a pliable material such as rubber, nylon, or the like.

The terms “snug fit,” “snuggly receive,” and “snuggly held” can be used interchangeable herein and shall mean very close or tight fitting such that an object does not move without a threshold force being applied. For example, when a cable is snuggly received within a gap between a first pliable member and a second pliable member that cable has a diameter or length that is slightly larger than the gap such that the cable undergoes compression forces from the pliable wings of each pliable member. Still, the cable is of slight enough diameter that it does fit within the gap.

The phrase “linear force” when used herein refers to any force in a certain direction. To this end, 100% of a force does not have to be in a certain direction. Instead, 95% of a force may be in one direction and 5% may be in another direction and still be considered a linear force.

Provided is a cable holding assembly for an electronic device that includes a cable holding device that can have a one-piece strip body with multiple arcuate slots, or cable openings, with one-way-valve type gaps that grip each individual cable. The cable holding device can be molded with a flexible material such as rubber or nylon. When a cable is pushed into the gap from above, flanges, or pliable wings are forced open, but maintain pressure on the sides of the cable. The angle of the pliable wings (e.g., flanges) of side-by-side pliable members act as a one-way valve, enabling the cable to move forward when incurring a linear force towards an input port of the electronic device, but not backwards if a linear force in the opposite direction (e.g., away from input port of the electronic device) is applied. As a result an input end (e.g., plug) of the cable can be pushed forward into the port but does not slide backwards out of the port. To remove, the cable can be pulled upwards out of the top opening of the gap so the input end (e.g., plug) can be pulled out of the port without incurring resistant forces from the adjacent wings (e.g. flanges). In an example embodiment the cable holding device can be custom designed to have the correct number of pliable members and spacing therebetween such that each cable aligns with a corresponding input port of the electronic device. Alternatively, the cable holding device can simply have multiple unused openings and still be used even if the gaps do not align with a corresponding input port of the electronic device.

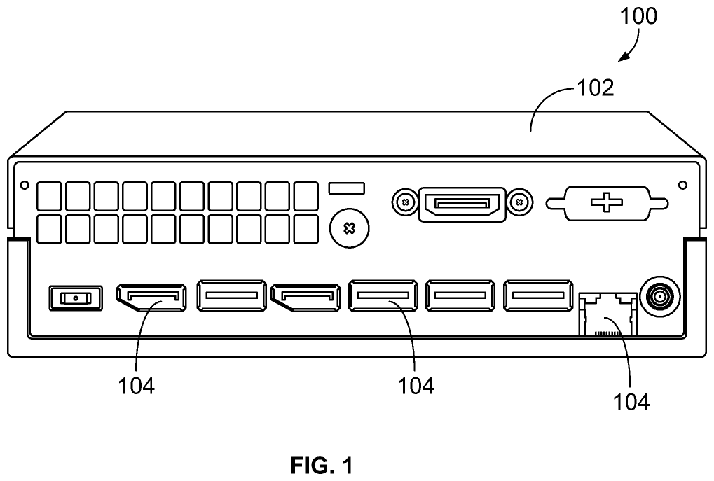

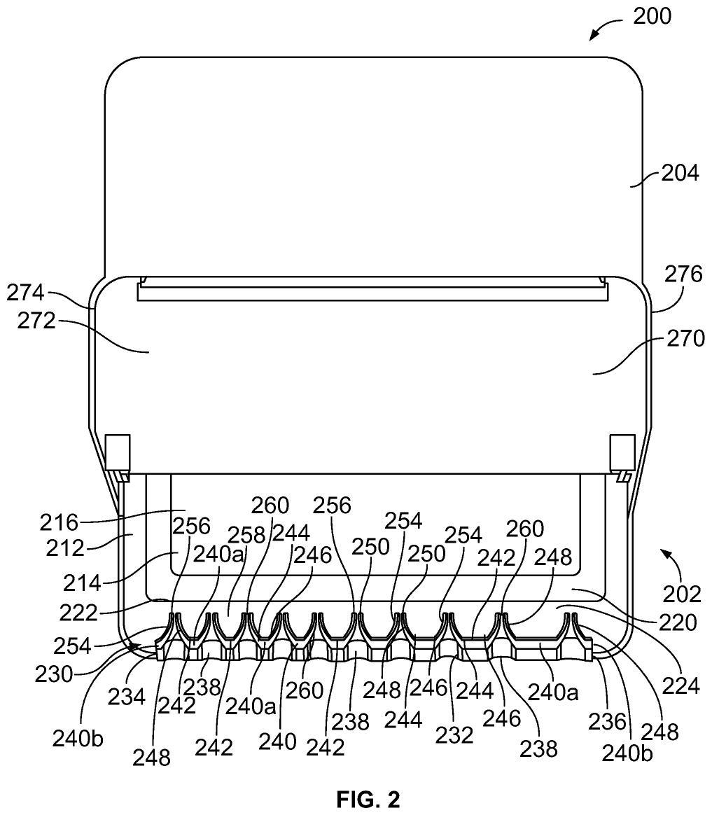

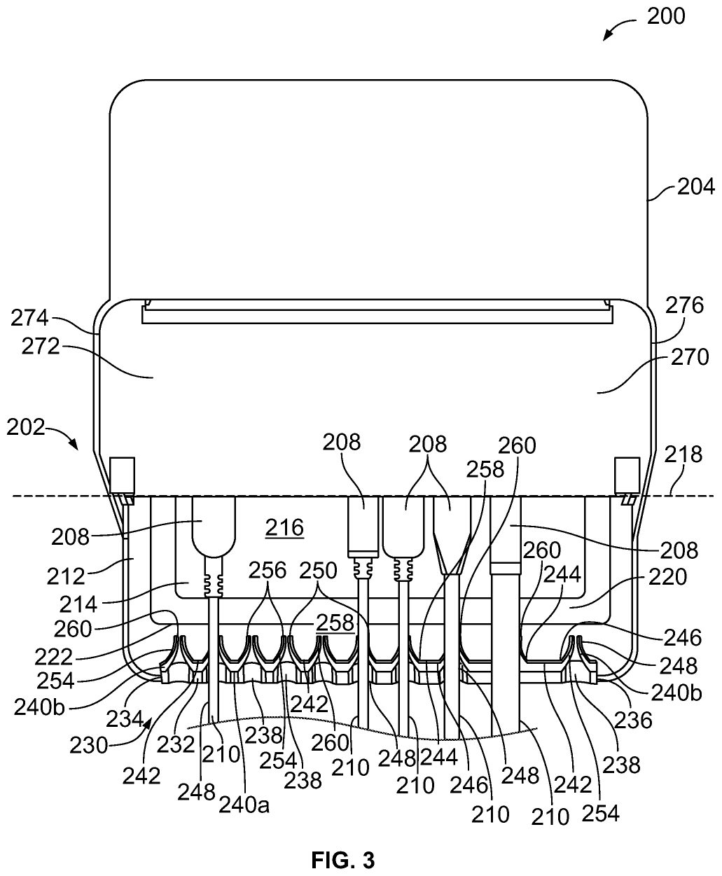

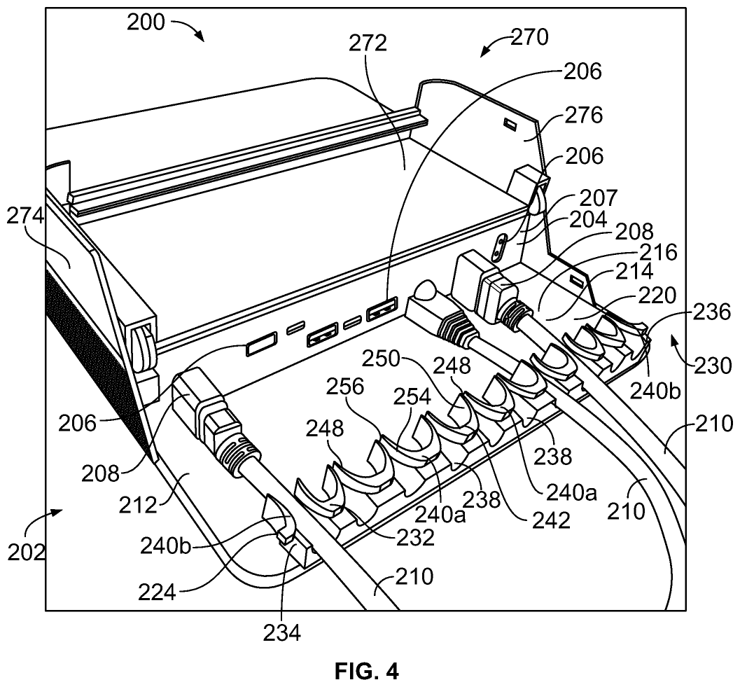

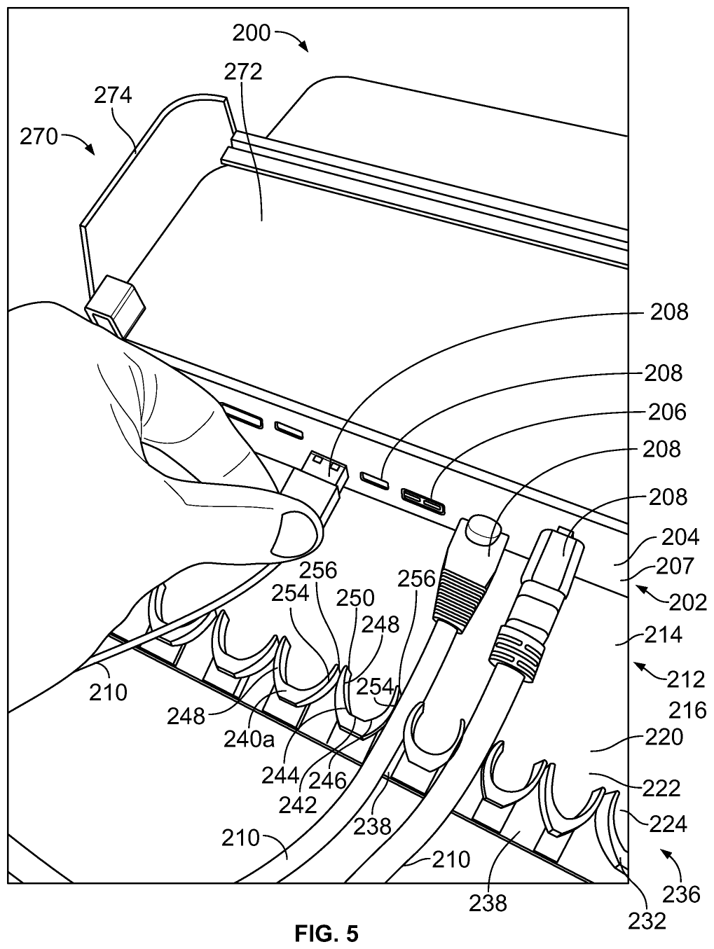

FIG. 1 illustrates an electronic device 100 that may be implemented in connection with a cable holding assembly (FIGS. 2-5). The electronic device can include a body 102 that can include numerous input ports 104 that can receive cables (FIGS. 2-5) for providing functionality for the electronic device 100. The electronic device can be a personal computer, laptop computer, iPad, or the like, though the holding assembly as described herein is most often utilized with a personal computer or other electronic device that remains stationary.

FIGS. 2-5 show example electronic devices 200 that include a cable holding assembly 202. In one example the electronic device of FIG. 1 is the electronic device of FIGS. 2-5. The electronic device 200 in this example embodiment includes a base subassembly 204 that has numerous electronic device input ports 206 at a back side 207 for receiving the input end 208 (e.g., plug) of a cable 210. While in the examples of FIGS. 2-5 the electronic device input ports 206 are illustrated on a back side 207 of the electronic device, in other examples the numerous electronic device input ports 206 can similar be located on a different side of the electronic device 200.

As also illustrated in FIGS. 2-5 the numerous electronic device input ports 206 can have different shapes and sizes. Some are generally rectangular and have a lateral axis that is greater than their longitudinal axis. Other electronic device input ports 206 are generally rectangular and have a lateral axis that is less than their longitudinal axis. Other electronic device input ports 206 can have a round shape, while others generally have a square shape. The electronic device input ports 206 can also have a similar shape but a different size. As a result, the shape of the input end 208 of each cable 210 can differ in size and shape to fit within a corresponding electronic device input port 206. As a result of the different sized electronic device input ports 206 and input ends 208 of the cables 210 the spacing between the individual electronic device input ports 206 is often not the same or equidistant. Instead, larger sized electronic device input ports 206 typically have larger input ends 208 that they receive that take up more room across the back side of the electronic device than smaller sized electronic device input ports 206 and their corresponding input ends 208. As a result, to ensure an adjacent electronic device input port 206 is not covered or inaccessible because a larger sized input 208 is within the adjacent electronic device input port 206, greater spacing between the adjacent electronic device input ports 206 is provided compared to if side-by-side electronic device input ports 206 were smaller in size. To this end, the cables 210 of the larger sized input ends 208 also typically have a larger diameter than cables having smaller sized input ends 208. Consequently, the spacing required between the electronic device input ports 206 can vary based on the particular electronic device 200 and the electronic device input ports 206 that a particular electronic device 200 has.

The cable holding assembly 202 extends from the base subassembly 204 of the electronic device 200. While in this example the cable holding assembly 202 extends from the back 207 of the base subassembly 204, in other example embodiments the cable holding assembly 202 could extend from either side of the base subassembly 204, or the front of the base subassembly. To this end, in some embodiments a base subassembly 204 may include a first cable holding assembly on one side (such as the back side) and have a second cable holding assembly on another side. In one example the cable holding assembly is of one-piece construction with the base subassembly 204 and part of the electronic device 200. Alternatively, the cable holding assembly 202 can be a detachable accessory for an electronic device 200 that can be detachably secured to an end or side of the electronic device. The cable holding assembly may be detachably secured by any mechanical device, magnetic device, etc. including the use of fasteners, clips, locking tabs, Velcro, adhesive, form fitting, or the like. In each instance the cable holding assembly 202 may be a separate component from the electronic device 200 that is secured in place.

The cable holding assembly 202 can include a body 212 of size and shape to couple to the electronic device and to contain input ends 208, (e.g. plugs) of the numerous cables 210. In one example the body 212 may removably couple to the electronic device such that the body 212 can be coupled to an existing electronic device. In this manner the cable holding assembly may be a separate stand-alone device compared to the electronic device. In another example the cable holding assembly can be of one-piece construction with the electronic device.

In one example the body 212 includes a bottom tray 214 that includes a bottom surface 216 configured to accommodate the input ends 208. In particular, the electronic device input ports 206 are generally centrally located along a lateral axis 218 of the back side 207 (for this example embodiment) of the electronic device. In addition, the input ends 208 are often of size and shape that do not to have a longitudinal height the extends past the top or bottom of the base subassembly 204. Therefore, in one example the bottom surface 216 of the bottom tray 214 can be flush with the bottom surface of the base subassembly 204 to accommodate input ends 208 that are inserted into the electronic device input ports 206. The bottom tray 214 can then extend away from the base subassembly 204 while remaining flush and extend into an inclined surface 220 that leads to an edge 222 that forms a cable surface 224 that is generally flat. In particular, because the cable 210 extends from the input end 208, the cable extends orthogonal from the lateral axis 218 of the back side and parallel to the bottom surface 216 of the bottom tray 214. Therefore, the cable surface 224 approximately shares the same plane of the lateral axis 218 of the back side 207 to allow the cable to be as straight as possible when extending from the input end 208 to the cable surface 224.

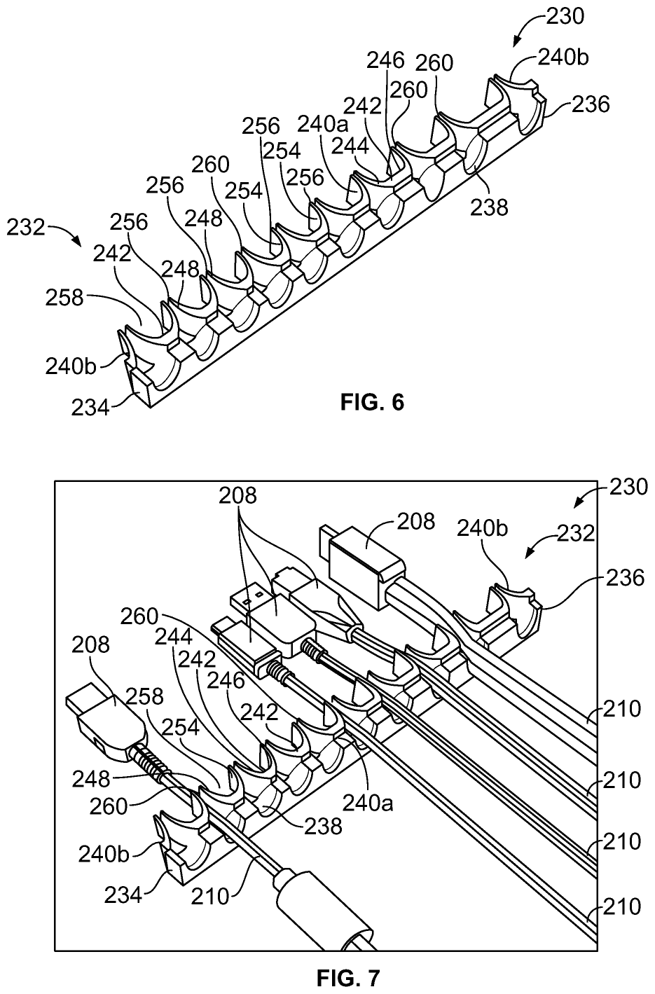

Coupled to the cable surface 224 is a cable holding device 230. FIGS. 6 and 7 illustrate the cable holding device 230 in greater detail. In one example the cable holding device is removably coupled to the cable surface 224. In this manner the cable holding device can be retrofit, or coupled to an existing electronic device that does not include a cable holding device. Alternatively, the cable holding device may be secured to the cable surface such that cable holding device 230 cannot be removed without applying excess force.

The cable holding device 230 can be made of a pliable material including rubber, nylon, or the like. The cable holding device 230 has a cable holding body 232 that extends from a first end 234 to a second end 236 generally parallel to the back side 207 of the electronic device. The cable holding body 232 includes numerous arcuate slots 238 each configured to receive a cable 210. In one example the arcuate slots 238 can have different diameters to accommodate cables 210 having different diameters. In particular, each arcuate slot 238 is sized and shaped to receive a corresponding cable 210 associated with the electronic device input port 206 that aligns with the arcuate slot 238. To this end, if the arcuate slot corresponds to an input port 206 for a serial port that receives a serial cable with a larger diameter, the diameter of the arcuate slot 238 can be larger to accommodate the larger diameter cable. Whereas if the input port 206 is a USB type of port the arcuate slot can be smaller (than the arcuate slot corresponding to the serial port) to accommodate the smaller diameter cable. To this end, in one example the spacing between each of the arcuate slots 238 is not equidistant or the same, and instead varies depending on the corresponding electronic device input ports 206. In all, the arcuate slots 238 can be spaced such that each arcuate slot aligns with a corresponding electronic device input port 206 and is of size and shape to receive a cable 210 that corresponds with that electronic device input port 206.

The holding device 230 also includes numerous side-by-side pliable members 240A, 240B, or tabs. In one example the pliable members 240A, 240B are of one-piece construction with the holding body 232. Alternatively the pliable members 240A, 240B are detachably coupled to the holding body 232 to allow removal and replacement of individual pliable members 240A, 240B.

The interior pliable members 240A each have a generally frustoconical shape with a flat surface 242 that extends from a first pliable member end 244 to a second pliable member end 246. In one example, the flat surface 242 defines a coupling location or transition with the rest of the holding body 232.

A first pliable wing 248 extends arcuately from the first pliable member end 244 of the flat surface 242 towards a corresponding electronic device input port 206 and terminates at a first pliable wing end 250. In one example, the first pliable wing 248 is generally arcuate in shape such that the first pliable wing 248 curves so a first pliable wing end 250 is generally in parallel spaced relation to the back end 207. In other example embodiments the first pliable wing 248 can be straight, partially curved, or the like in extending from the first pliable member end 244.

Similarly, a second pliable wing 254 in one example can extend arcuately from the second pliable member end 246 of the flat surface 242 towards a corresponding electronic device input port 206 and terminate at a second pliable wing end 256. In another example the second pliable wing 254 can also be different shapes similar to the first pliable wing 248. Still, the second pliable wing 254 extends towards a different corresponding electronic device input port 206 than the first pliable wing 248. In addition, similar to the first pliable wing 248, the second pliable wing 254 can curve such that the second pliable wing end 256 is also generally in parallel spaced relation to the back end 207. In addition, the first pliable wing end 250 and second pliable wing end 256 have an open end 258 spaced in between.

Meanwhile, the exterior pliable members 240B represent the outer most pliable members of the cable holding device 230 with one exterior pliable member 240B provided at the first end 234 of the cable holding body 232 and the exterior pliable member 240B provided at a second end 236 of the cable holding body 232. Each of the exterior pliable members 240B simply has a single wing 248 or 256.

A gap 260 is formed between the first pliable wing end 250 of a first pliable member and a second pliable wing end 256 of an adjacent second pliable member. The cable holding device 230 is configured such that the gap 260 aligns with both a corresponding input port 206 of the electronic device and an arcuate slot 238 of the holding body 232 that also aligns with the same corresponding input port 206. As a result, the gap 260 aligns the cable 210 and corresponding input end 208 with the corresponding input port 206.

The cable holding assembly 202 also includes a cover 270 or lid. In one example the cover 270 can be rotatably coupled to the body 212 to move from an open position to a closed position. Alternatively, the cover could be slidably mounted, form fit, or the like with the body. In particular, the purpose of the cover 270 is to conceal the input ends 208 of the cables 210 within the cable holding assembly 202 while also allowing access to the input ends 208 and cables 210 for plugging and unplugging into the corresponding input ports 206. To this end, the cover 270 provides a more aesthetically pleasing appearance while providing functionality associated with plugging in and unplugging the individual cables. The cover 270 in one example may have a top 272 rotatably coupled to the body 202 at a hinge 274. Extending from the top 272 is a first side surface 274 and a second side surface 276 where the first and second side surfaces 274, 276 are in parallel spaced relation. While in this example embodiment the cover includes the first and second side surfaces 274, 276, in other examples one or more of the side surfaces 274, 276 of the cover 270 may be part of the body 202 itself. To this end the cover 270 in one example may only consist of a top 272 that is received by the first and second side surfaces of the body 202.

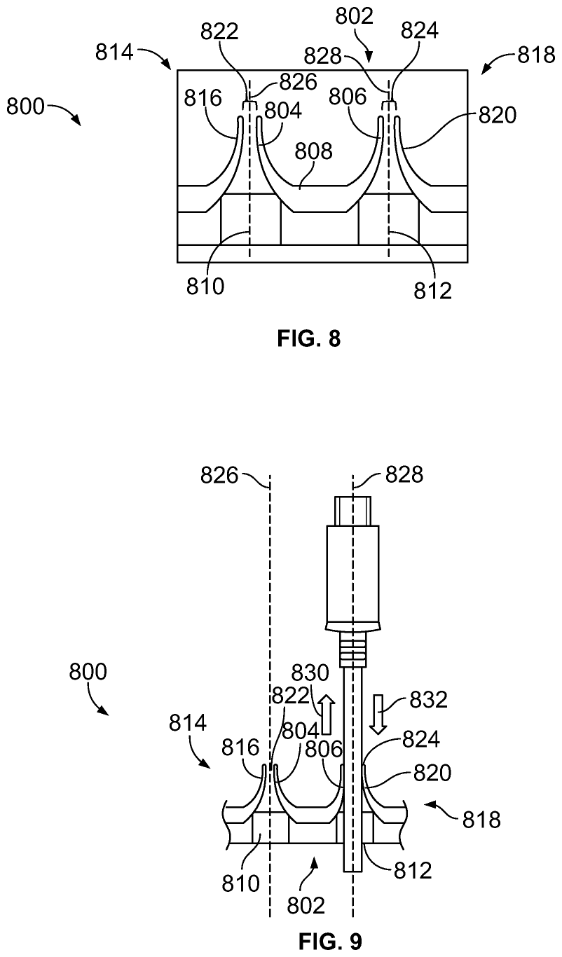

FIGS. 8 and 9 illustrate partial views of a cable holding device 800 that are provided to describe the functioning and operation of the cable holding device 800. In particular, FIGS. 8 and 9 illustrate a first pliable member 802 that includes a first pliable wing 804 and second pliable wing 806 with a flat surface 808 disposed therebetween. In one example the width of the flat surface 808 depends on the size of the input ends of the cables located within the first arcuate slot 810 adjacent the first pliable wing 804 and the second arcuate slot 812 that is adjacent the second pliable wing 806. For example, if the width of the input end of the cable in the first arcuate slot 810 and second arcuate slot 812 are both large, the width of the flat surface 808 is significantly greater than if the width of the input end of the cable in the first arcuate slot 810 and second arcuate slot 812 are both small. In this manner, the width of the flat surface is selected based on the sizes of the input ends of the adjacent cables.

On the left of the first pliable member 802 and first arcuate slot 810 is a second pliable member 814 that is illustrated with only a second pliable wing 816 of the second pliable member 814 (though such second pliable member 814 could have a first pliable wing). Meanwhile, on the right of the first pliable member 802 and second arcuate slot 812 is a partial third pliable member 818 where only a first pliable wing 820 is illustrated (though such third pliable member 818 would have a second pliable wing).

As a result of the side-by-side arrangement of the pliable members 802, 814, 818, a first gap 822 is formed between the first pliable wing 804 of the first pliable member 802 and the second pliable wing 816 of the second pliable member 814. In addition, a second gap 824 is formed between the second pliable wing 806 of the first pliable member 802 and the first pliable wing 820 of the third pliable member 818. The size of each gap 822, 824 can be based on the size of cable that is to be inserted into a corresponding gap 822, or 824 and corresponding arcuate slot 810 or 812. In this manner, the first pliable wing 804 of the first pliable member 802 may be spaced a further distance from the second pliable wing 816 of the second pliable member 814 than the second pliable wing 806 is spaced from the first pliable wing 820 of the third pliable member 818 such that the first gap 822 has a greater width than the second gap 824. In particular, the first gap 822 is able to snuggly receive a cable with a larger diameter than the second gap 824. Alternatively, the second gap 824 may have a greater width than the first gap 822. In this manner the spacing between the individual pliable members 802, 814, 818 can be selected based on the diameter of the cable to be received within the gap 822 or 824 and corresponding arcuate slot 810, 812.

As described above, the cable holding device 800 is configured such that the first gap 822 aligns with both a corresponding input port of the electronic device and the first arcuate slot 810 that also aligns with the same corresponding input port. In this manner a cable corresponding to that input port can be inserted from above between the first pliable wing 804 of the first pliable member 802 and the second pliable wing 816 of the second pliable member 814. When the cable is pushed downwardly with only a downward force towards the cable surface, only the frictional forces of the corresponding pliable wings 804, 816 resist the pushing force, because the width of the first gap 822 is slightly less than the diameter of the cable. As the cable is inserted between the corresponding pliable wings 804, 816, each pliable wing 804, 816 deflects or moves away from a first center axis 826 of the first gap 822 (compared to second center axis 828 of the second gap 824). Still, because each pliable wing 804, 816 is pliant, each desires to move toward the first center axis 826 back to their original position. As a result, the corresponding cable is snuggly held between the corresponding pliable wings 804, 816 such that minor forces do not affect the cable and input end of the cable once the input end is inserted into a corresponding input port of an electronic device. This results in the input end not becoming randomly dislodged during use, reducing frustrations of a user of the electronic device.

In addition, once the cable is pushed, or snapped, into place between the corresponding pliable wings 804, 816 to provide a snug fit, if the input end of the cable still needs to move towards the input port so that the input end can be inserted into the input port, a linear force 830 towards the input port can be placed on the cable. As a result of the design of the corresponding pliable wings 804, 816, each pliable wing 804, 816 deflects inwardly away from the corresponding center axis 826. In particular, the end of the flat surface that can represent the beginning of the pliable wing 804, 816 functions as a fulcrum point upon which the pliable wing 804 or 816 rotates about. Consequently, when a linear force 830 is provided towards the input port, the second pliable wing 816 moves counterclockwise to deflect away from the center axis 826 while the first pliable wing 804 rotates clockwise also away from the center axis 826.

In contrast, when a linear force 832 is provided away from the input port, the cable pulls each pliable wing 804, 816 towards the center axis 826 resulting in a compression force being formed on the cable between the respective pliable wings 804, 816. In this manner, the pliable wings function similar to a one-way valve wherein movement of the cable in a first linear direction is permitted, while movement in an opposite second linear direction is resisted or prevented. Thus, when the input end and cable need to be pushed towards the input port for insertion, each pliable wing 804, 816 deflects away from the center axis 826 and thus the force and corresponding movement is not resisted. In contrast, when the input end and corresponding cable are being pulled away from the input port the force and movement is resisted by the pliable wings 804, 816 as the pliable wings compress the cable therebetween. While in one example the pliable wings 804, 816 may be arcuate pliable wings as illustrated that deflect away from the center axis 826 as a result of the first linear force 830 and deflect towards the center axis 826 to provide a compression force when a second opposite linear force is applied, other shapes that accomplish the same functionality may be provided.

Consequently, while the input end can be easily inserted into a corresponding input port, an unwanted outside force cannot pull the cable and corresponding input end out of the input port. This greatly reduces the risk of an input end randomly being pulled out of an input port during use of the electronic device. Additionally, when a user wants to remove the input end of the cable from an input port, they only need to provide an upward force to overcome the snug fit of the cable within the first gap 822.

It is to be understood that the subject matter described herein is not limited in its application to the details of construction and the arrangement of components set forth in the description herein or illustrated in the drawings hereof. The subject matter described herein is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Further, in the following claims, the phrases “at least A or B”, “A and/or B”, and “one or more of A and B” (where “A” and “B” represent claim elements), are used to encompass i) A, ii) B and/or iii) both A and B.

It is to be understood that the above description is intended to be illustrative, and not restrictive. For example, the above-described embodiments (and/or aspects thereof) may be used in combination with each other. In addition, many modifications may be made to adapt a particular situation or material to the teachings herein without departing from its scope. While the dimensions, types of materials and coatings described herein are intended to define various parameters, they are by no means limiting and are illustrative in nature. Many other embodiments will be apparent to those of skill in the art upon reviewing the above description. The scope of the embodiments should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects or order of execution on their acts.

What is claimed is:

1. A cable holding assembly for an electronic device comprising:
a cable holding device having a cable holding body removably coupled therein, the cable holding device having a first arcuate slot configured to receive a first cable and a second arcuate slot configured to receive a second cable;
a first pliable member disposed between the first arcuate slot and the second arcuate slot;
the first pliable member having a first pliable wing; and
a second pliable member having a second pliable wing wherein a first gap having a center axis is formed between the first pliable wing of the first pliable member and the second pliable wing of the second pliable member;
wherein the first pliable wing of the first pliable member and second pliable wing of the second pliable member are both configured to deflect away from the center axis in response to a first linear force applied by the first cable disposed within the first gap;
wherein the first pliable wing of the first pliable member and second pliable wing of the second pliable member are both configured to deflect towards the center axis in response to a second linear force applied by the first cable disposed within the first gap to apply a compression force on the first cable; and
wherein the first linear force is in an opposite direct to the second linear force.

2. The cable holding assembly of claim 1, wherein the first pliable wing and second pliable wing are each configured to compress the cable between one another when the second linear force is applied.

3. The cable holding assembly of claim 1, wherein the first pliable wing is a first arcuate wing and the second pliable wing is a second arcuate wing.

4. The cable holding assembly of claim 1, wherein the first pliable member includes a flat surface that extends between the first pliable wing and the second pliable wing.

5. The cable holding assembly of claim 4, wherein a width of the flat surface is based at least in part on the width of an input end of the cable.

6. The cable holding assembly of claim 1, wherein a width of the first gap is based at least in part on a diameter of the cable.

7. The cable holding assembly of claim 1, wherein the first gap is configured to snuggly receive the cable.

8. The cable holding assembly of claim 1, further comprising:
a body configured to couple to the electronic device and having a bottom tray configured to receive at least one input end of the cable.

9. The cable holding assembly of claim 8, wherein the bottom tray extends into a cable surface that includes the cable holding device.

10. The cable holding assembly of claim 9, further comprising:
a cover coupled to the body and configured to allow access to the cable.

11. A cable holding assembly for an electronic device comprising:
a body configured to removably couple to an electronic device and having a bottom tray configured to receive a first input end of a first cable and a second input end of a second cable while the first input end and second input end are inserted into a corresponding input port of the electronic device;
a cable holding device secured to the body and having a cable holding body with a first arcuate slot configured to receive the first cable and aligned with a first corresponding input port and a second arcuate slot configured to receive the second cable and aligned with a second corresponding input port;
the cable holding device further including a first pliable member disposed between the first arcuate slot and the second arcuate slot;
the first pliable member having a first pliable wing; and
a second pliable member having a second pliable wing wherein a first gap having a first center axis is formed between the first pliable wing and the second pliable wing;
wherein the first center axis aligns with the first corresponding input port;
wherein the first pliable wing of the first pliable member and second pliable wing of the second pliable member are both configured to deflect away from the first center axis in response to a first linear force applied by the first cable;
wherein the first pliable wing of the first pliable member and second pliable wing of the second pliable member are both configured to deflect towards the first center axis in response to a second linear force applied by the first cable; and
wherein the first linear force is in an opposite direct to the second linear force.

12. The cable holding assembly of claim 11,
wherein the first pliable member has a second pliable wing and the cable holding device further includes a third pliable member having a first pliable wing; wherein a second gap is formed between the second pliable wing of the first pliable member and the first pliable wing of the third pliable member; and wherein the second pliable wing of the first pliable member and the first pliable wing of the third pliable member are both configured to deflect away from the second center axis in response to a first linear force applied by the second cable and deflect towards the second center axis in response to a second linear force applied by the second cable, and wherein the first linear force applied by the second cable is in an opposite direction to the second linear force applied by the second cable.

13. The cable holding assembly of claim 12, wherein the second gap is configured to receive the second cable and align with the second corresponding input port.

14. The cable holding assembly of claim 12, wherein the first center axis is parallel to the second center axis.

15. The cable holding assembly of claim 11, wherein the first pliable wing is a first arcuate wing and the second pliable wing is a second arcuate wing.

16. The cable holding assembly of claim 11, wherein the first pliable member is detachable from the cable holding assembly.

17. The cable holding assembly of claim 11, further comprising a third arcuate slot wherein a first distance between the first arcuate slot and the second arcuate slot is a different distance than a second distance between the second arcuate slot and the third arcuate slot.

18. The cable holding assembly of claim 11, wherein the cable holding device and the body are of one-piece construction.

19. A cable holding assembly for an electronic device comprising:
a body configured to couple to an electronic device and having a bottom tray configured to receive at least one input end of a cable while the at least one input end is inserted into an input port of the electronic device;
the bottom tray extending into a cable surface having a similar height to the input port of the electronic device;
a cable holding device secured to the cable surface comprising:
a cable holding body with a first arcuate slot configured to receive a first cable and a second arcuate slot configured to receive a second cable;
a first pliable member disposed between the first arcuate slot and the second arcuate slot;
the first pliable member having a first pliable wing; and
a second pliable member having a second pliable wing wherein a first gap having a center axis is formed between the first pliable wing of the first pliable member and the second pliable wing of the second pliable member;
wherein the first pliable wing of the first pliable member and second pliable wing of the second pliable member are both configured to deflect away from the center axis in response to a first linear force applied by a cable disposed within the first gap;
wherein the first pliable wing of the first pliable member and second pliable wing of the second pliable member are both configured to deflect towards the center axis in response to a second linear force applied by the cable disposed within the first gap; and
wherein the first linear force is in an opposite direct to the second linear force.

20. The cable holding assembly of claim 19, wherein the first pliable member has a second pliable wing and the cable holding device further includes a third pliable member having a first pliable wing; wherein a second gap is formed between the second pliable wing of the first pliable member and the first pliable wing of the third pliable member; and wherein the second pliable wing of the first pliable member and the first pliable wing of the third pliable member are both configured to deflect away from the second center axis in response to a first linear force applied by the second cable and deflect towards the second center axis in response to a second linear force applied by the second cable, and wherein the first linear force applied by the second cable is in an opposite direction to the second linear force applied by the second cable.
